(19) United States
(12) Patent Application Publication
(10) Pub. No.: US 2024/0060174 A1
(43) Pub. Date: Feb. 22, 2024

(54) METHOD OF FORMING MATERIAL WITHIN A RECESS

(71) Applicant: ASM IP Holding B.V., Almere (NL)

(72) Inventors: Makoto Igarashi, Tokyo (JP); Shinya Yoshimoto, Tokyo (JP); Jhoelle Roche Guhit, Tokyo (JP); Ling Chi Hwang, Tokyo (JP)

(21) Appl. No.: 18/234,549

(22) Filed: Aug. 16, 2023

Related U.S. Application Data
(60) Provisional application No. 63/399,477, filed on Aug. 19, 2022.

(51) Int. Cl. C23C 16/04

(52) U.S. Cl. CPC C23C 16/045

(57) ABSTRACT

Methods and systems of forming material within a recess are disclosed. Exemplary methods include forming a flowable material at a first temperature (T1) within a reaction chamber, the flowable material forming deposited material within the recess, treating the deposited material to form treated material, and heating the substrate including the treated material at a second temperature (T2) to remove a portion of the deposited material.

### CROSS-REFERENCE TO RELATED APPLICATIONS

This application claims priority to U.S. Provisional Patent Application Ser. No. 63/399,477 filed Aug. 19, 2022 titled METHOD OF FORMING MATERIAL WITHIN A RECESS, the disclosure of which is hereby incorporated by reference in its entirety.

### FIELD OF INVENTION

The present disclosure generally relates to methods suitable for use in the manufacture of electronic devices. More particularly, examples of the disclosure relate to methods suitable for forming material within a gap on a substrate surface.

### BACKGROUND OF THE DISCLOSURE

During the manufacture of devices, such as semiconductor devices, it is often desirable to fill features (e.g., trenches or vias) on the surface of a substrate with insulating or dielectric material. For example, insulating material, can be used to fill gaps for a variety of applications, such as isolation of devices or device features.

One technique to fill gaps includes forming flowable material within a reaction chamber, wherein the flowable material flows within gaps on a surface of a substrate. Once the flowable material has flowed within the gaps, the flowable material can be treated to harden or densify the material.

Such techniques can work well for a variety of applications. However, typical techniques of filling gaps with flowable material often do not fill gaps of varying aspect ratios with a uniform (e.g., uniform height) of material. Rather, with typical flowable material processes, relatively non-uniform distribution of flowable material within gaps can occur. For example, a height of a flowable material within a high aspect ratio gap can be much greater than a height of the flowable material in a low aspect ratio gap.

For many applications, it may be desirable to uniformly fill gaps of varying aspect ratios and/or other size difference relatively uniformly, such that the material within each gap is of about the same height. Accordingly, improved methods for uniformly forming material (e.g., based on a height of material) within a gaps, are desired.

Any discussion, including discussion of problems and solutions, set forth in this section, has been included in this disclosure solely for the purpose of providing a context for the present disclosure, and should not be taken as an admission that any or all of the discussion was known at the time the invention was made or otherwise constitutes prior art.

### SUMMARY OF THE DISCLOSURE

Various embodiments of the present disclosure relate to methods of forming material within a recess on a surface of a substrate. Such methods can be used in, for example, the formation of electronic devices, such as semiconductor devices. While the ways in which various embodiments of the present disclosure address drawbacks of prior methods are discussed in more detail below, in general, exemplary embodiments of the disclosure provide improved methods of uniformly (e.g., based on a height of material) filling a gap with material.

In accordance with various embodiments of the disclosure, a method of forming material within a recess on a surface of a substrate is provided. An exemplary method includes providing a substrate within a reaction chamber, forming a flowable material at a first temperature (T1) within the reaction chamber, the flowable material forming deposited material within the recess, treating the deposited material using activated species to form treated material, and heating the substrate at a second temperature (T2) to remove a portion of the deposited material. In accordance with various aspects of these embodiments, T2 is greater than T1. A temperature (T3) during the step of treating is greater than or equal to T1 and/or less than T2. The step of forming the flowable material can include a cyclical deposition process. In accordance with examples of the disclosure, the deposited material comprises silicon carbon nitride. In accordance with further examples, the precursor used to form the flowable material can include silicon and nitrogen. By way of examples, the precursor can include one or more of a silazane, a silylamine, or a silicon alkylamine. A reactant used to form the flowable material can include one or more of argon, nitrogen, or hydrogen. During the step of heating, one or more of argon, nitrogen, helium, hydrogen, and/or ammonia can be provided to the reaction chamber. In accordance with further examples of the disclosure, during the step of treating, a gas comprising hydrogen can be provided to the reaction chamber. In accordance with yet further examples, the method can include repeating the steps of forming the flowable material, treating the deposited material, and heating the substrate—e.g., to fill the gap. In some cases, the method can include repeating the steps of forming the flowable material and treating the deposited material prior to the step of heating the substrate.

In accordance with yet further exemplary embodiments of the disclosure, a structure is formed using a method as described herein.

In accordance with yet further exemplary embodiments of the disclosure, a system is provided for performing a method and/or for forming a structure as described herein.

These and other embodiments will become readily apparent to those skilled in the art from the following detailed description of certain embodiments having reference to the attached figures; the invention not being limited to any particular embodiment(s) disclosed.

### BRIEF DESCRIPTION OF THE DRAWING FIGURES

A more complete understanding of exemplary embodiments of the present disclosure can be derived by referring to the detailed description and claims when considered in connection with the following illustrative figures.

FIG. 1 illustrates a method in accordance with exemplary embodiments of the disclosure.

FIG. 2 illustrates structures, showing pattern-loading effects.

FIG. 3 illustrates structures formed in accordance with examples of the disclosure.

FIG. 4 illustrates a reactor system in accordance with exemplary embodiments of the disclosure.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below.

The present disclosure generally relates to methods forming material within a recess on a surface of a substrate. Exemplary methods described herein can be used to form structures that can be used in a variety of applications, such as cell isolation in 3D cross point memory devices, self-aligned vias, dummy gates, reverse tone patterns, PC RAM isolation, cut hard masks, DRAM storage node contact (SNC) isolation, and the like.

In this disclosure, gas can refer to material that is a gas at normal temperature and pressure, a vaporized solid and/or a vaporized liquid, and may be constituted by a single gas or a mixture of gases, depending on the context. A gas other than a process gas, i.e., a gas introduced without passing through a gas distribution assembly, such as a showerhead, other gas distribution device, or the like, may be used for, e.g., sealing a reaction space, which includes a seal gas, such as a noble gas. In some cases, such as in the context of deposition of material, the term precursor can refer to a compound that participates in the chemical reaction that produces another compound, and particularly to a compound that constitutes a film matrix or a main skeleton of a film, whereas the term reactant can refer to a compound, in some cases other than a precursor, that activates a precursor, modifies a precursor, or catalyzes a reaction of a precursor; a reactant may, in some cases, provide an element (such as H or N) to a film matrix and become a part of the film matrix when, for example, power (e.g., radio frequency (RF) power) is applied. In some cases, the terms precursor and reactant can be used interchangeably. The term inert gas refers to a gas that does not take part in a chemical reaction to an appreciable extent and/or a gas that excites a precursor (e.g., to facilitate polymerization of the precursor) when, for example, power (e.g., RF power) is applied to form a plasma; an inert gas may not become a part of a film matrix to an appreciable extent. When excited (e.g., via a plasma), an inert gas, including, for example, one or more noble gases, can be considered a reactant. A carrier gas can be an inert gas, such as a noble gas, nitrogen, or the like.

As used herein, the term substrate can refer to any underlying material or materials that may be used to form, or upon which, a device, a circuit, or a film may be formed. A substrate can include a bulk material, such as silicon (e.g., single-crystal silicon), other Group IV materials, such as germanium, or compound semiconductor materials, such as Group Ill-V or Group II-VI semiconductors, and can include one or more layers overlying or underlying the bulk material. Further, the substrate can include various features, such as gaps, also referred to herein as recesses, (e.g., trenches or vias), lines or protrusions, such as lines having recesses formed therebetween, and the like formed on or within or on at least a portion of a layer or bulk material of the substrate. By way of examples, one or more features (e.g., recesses) can have a width of about 10 nm to about 100 nm, a depth or height of about 30 nm to about 1,000 nm, and/or an aspect ratio of about 3 to 100. The substrate can include features of varying dimensions and aspect ratios.

In some embodiments, film refers to a layer extending in a direction perpendicular to a thickness direction. In some embodiments, layer refers to a material having a certain thickness formed on a surface and can be a synonym of a film or a non-film structure. A film or layer may be constituted by a discrete single film or layer having certain characteristics or multiple films or layers, and a boundary between adjacent films or layers may or may not be clear and may or may not be established based on physical, chemical, and/or any other characteristics, formation processes or sequence, and/or functions or purposes of the adjacent films or layers. The layer or film can be continuous—or not. Further, a single film or layer can be formed using multiple deposition cycles and/or multiple deposition and treatment cycles and/or multiple deposition, treatment, and heating cycles, as described below.

As used herein, the term silicon carbon material can refer to a layer whose chemical formula can be represented as including silicon and carbon. Layers comprising silicon-carbon material can include other elements, such as one or more of oxygen, nitrogen and hydrogen. Likewise, the term silicon carbon nitride material can refer to layer whose chemical formula can be represented as including silicon, carbon, and nitrogen. Layers comprising silicon carbon nitride material can include other elements, such as one or more of oxygen and hydrogen.

As used herein, the term structure can refer to a partially or completely fabricated device structure. By way of examples, a structure can be a substrate or include a substrate with one or more layers and/or features formed thereon.

As used herein, the term cyclic deposition process or cyclical deposition process can refer to a vapor deposition process in which deposition cycles, typically a plurality of consecutive deposition cycles, are conducted in a process chamber. Cyclic deposition processes can include cyclic chemical vapor deposition (CVD) and atomic layer deposition processes. A plasma cyclic deposition process can include one or more cycles that include plasma activation of a precursor, a reactant, and/or an inert gas. Generally, each deposition cycle of a plasma cyclic deposition process can include one or more of (1) pulsing a precursor to the reaction chamber, (2) pulsing a reactant to the reaction chamber, or (3) pulsing a plasma power or other activation source. In some cases, the cyclic deposition process can include two or all three of such steps.

In this disclosure, continuously or continuous can refer to without breaking a vacuum, without interruption as a timeline, without any material intervening step, without changing treatment conditions, immediately thereafter, as a next step, or without an intervening discrete physical or chemical structure between two structures other than the two structures in some embodiments and depending on the context.

A flowability (e.g., an initial flowability) can be determined as follows:

TABLE 1

| bottom/top ratio (B/T) | Flowability |
|---|---|
| 0 < B/T < 1 | None |
| 1 ≤ B/T < 1.5 | Poor |
| 1.5 ≤ B/T < 2.5 | Good |
| 2.5 ≤ B/T < 3.5 | Very good |
| 3.5 ≤ B/T | Extremely good |

where B/T refers to a ratio of thickness of film deposited at a bottom of a recess to thickness of film deposited on a top surface where the recess is formed, before the recess is filled. Typically, the flowability is evaluated using a wide recess having an aspect ratio of about 1 or less, since generally, the higher the aspect ratio of the recess, the higher the B/T ratio becomes. The B/T ratio generally becomes higher when the aspect ratio of the recess is higher. As used herein, a flowable film or material exhibits good or better flowability.

Flowability of film can be at least temporarily obtained when a volatile precursor is polymerized by activated species—e.g., formed using a plasma. The flowable material can deposit on a surface of a substrate when the gaseous precursor is activated or fragmented by energy provided by activated species, so as to initiate polymerization. The resultant polymer material can exhibit at least temporarily flowable behavior. After a short period of time (e.g., about 3.0 seconds), the film may no longer be flowable, but rather becomes solidified or hardened, and thus, a separate solidification process may not be employed.

In this disclosure, any two numbers of a variable can constitute a workable range of the variable, and any ranges indicated may include or exclude the endpoints. Additionally, any values of variables indicated (regardless of whether they are indicated with about or not) may refer to precise values or approximate values and include equivalents, and may refer to average, median, representative, majority, or the like, in some embodiments. Further, in this disclosure, the terms including, constituted by and having can refer independently to typically or broadly comprising, comprising, consisting essentially of, or consisting of in some embodiments. In this disclosure, any defined meanings do not necessarily exclude ordinary and customary meanings in some embodiments.

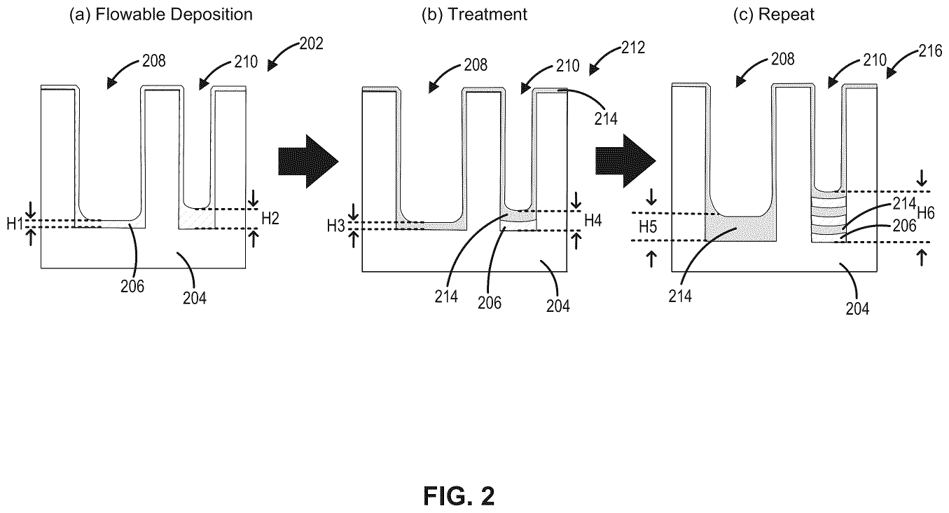

Techniques to fill recesses can include a flowable deposition step and a treatment step to modify (e.g., densify) the deposited material. FIG. 2 illustrates examples of how formation of material within gaps of varying aspect ratios can lead to uneven height of the deposited material within the recesses. The uneven heights of material can lead to uneven filling of the recesses—e.g., one recess may be filled before another recess is filled.

FIG. 2 (a) illustrates a structure 202, including a substrate 204 having a first recess 208 and a second recess 210, wherein an aspect ratio (height:width) of first recess 208 is less than an aspect ratio of second recess 210. As illustrated, a height H2 of deposited material 206 is greater within higher aspect ratio recess 210 than a height H1 of material 206 in lower aspect ratio recess 208.

FIG. 2 (b) illustrates a structure 212 after structure 202 has been exposed to a treatment step. As illustrated, a height difference of treated material 214 and untreated material within recess 210 and treated material within recess 208 can remain aftertreatment. Specifically, a height H4 of treated material 214 and untreated material 206 is greater within higher aspect ratio gap 210 than a height H3 of treated material 214 in lower aspect ratio gap 208.

FIG. 2 (c) illustrates a structure 216 after multiple deposition and treatment steps. As illustrated, a height difference between a height H5 of treated material in first recess 208 and a height H6 of treated material 214 and untreated material 206 in second recess 210 can increase with each cycle. As illustrated, because a treatment may be limited in a depth of deposited material that can be treated, a treatment process may not be able to treat all of the deposited material within higher aspect ratio recess 210. Thus, after a treatment step, material within recess 210 can include treated material 214 and deposited material 206 (i.e., undertreated or less treated or not treated material). The uneven height and/or combination of treated and untreated material within higher aspect ratio recesses leads to undesired variation in properties of material within the recesses.

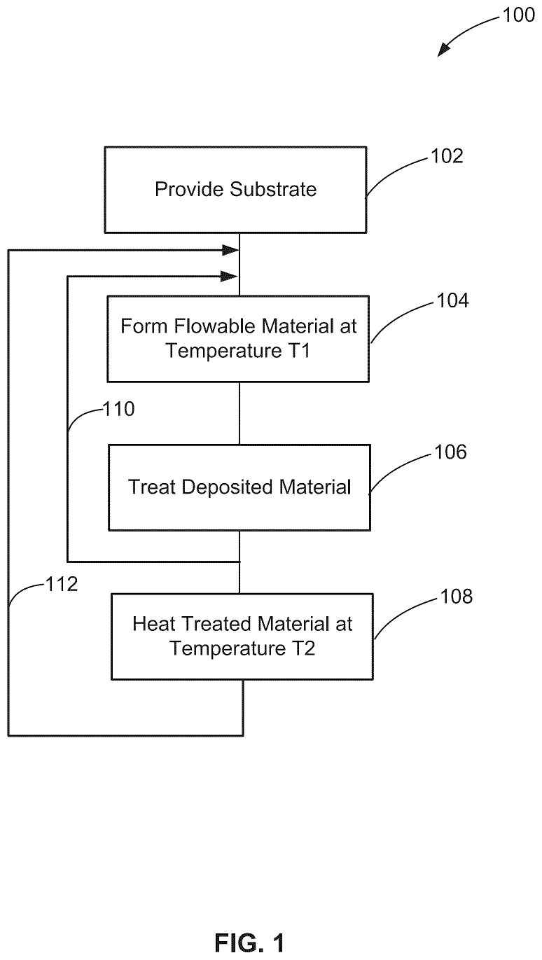

FIG. 1 illustrates a method 100 in accordance with examples of the disclosure. Method 100 can be used to form material within a recess on a surface of a substrate. In some cases, method 100 can be used to fill one or more patterned recesses (also referred to herein as gaps) on a surface of a substrate. Unlike traditional techniques, such as the method illustrated in FIG. 2, method 100 can be used to fill gaps or varying aspect ratios (e.g., a same height and varying widths) to a relatively uniform height during one or more cycles. Method 100 may be particularly well suited for filling recesses with material suitable for etch stop applications or gap fill applications.

Method 100 can be or include a cyclic process, such as a plasma cyclic deposition process, such as a plasma enhanced chemical vapor deposition (PECVD) process or a plasma enhanced atomic layer deposition (PEALD) process or a combination of PECVD and PEALD processes.

As illustrated, method 100 includes the steps of providing a substrate within a reaction chamber of a reactor (step 102), forming a flowable material at a first temperature (T1) within the reaction chamber, the flowable material forming deposited material within the recess (step 104), treating the deposited material using activated species within the reaction chamber to form treated material (step 106), and heating the treated material at a second temperature (T2) to remove a portion of the deposited material (step 108).

During step 102, a substrate is provided into a reaction chamber of a gas-phase reactor. The substrate can include any substrate noted herein and can have recesses of varying aspect ratios on the surface of the substrate.

In accordance with examples of the disclosure, the reaction chamber can form part of a cyclical deposition reactor, such as an atomic layer deposition (ALD) (e.g., PEALD) reactor or chemical vapor deposition (CVD) (e.g., PECVD) reactor. Various steps of methods described herein can be performed within a single reaction chamber or can be performed in multiple reaction chambers, such as reaction chambers of a cluster tool.

During step 102, the substrate can be brought to a desired temperature and/or the reaction chamber can be brought to a desired pressure, such as a temperature and/or pressure suitable for step 104. By way of examples, a temperature (e.g., of a substrate or a substrate support) within a reaction chamber (T1) can be less than or equal to 150° C. or between about 30° C. and about 100° C. or between about 50° C. and about 90° C. A pressure within the reaction chamber can be from, for example, about 300 Pa to about 2,000 Pa.

During step 104, a reactant and a precursor can be provided within the reaction chamber to form a flowable material at a first temperature (T1) within the reaction chamber. In accordance with examples of the disclosure, step 104 includes a cyclical deposition process. The cyclical deposition process can include providing a precursor to the reaction chamber for a precursor pulse, providing a reactant to the reaction chamber, and providing a plasma power for a deposition plasma power pulse period. In some cases, the reactant can be continuously provided to the reaction chamber during one or more cycles of step 104 and/or continuously during one or more of steps 104-108.

The reactant can include a gas comprising one or more of argon (Ar), nitrogen (N₂), or hydrogen (H₂), separately or any mixture thereof.

Exemplary precursors suitable for use during step 104 can include silicon and nitrogen. A precursor in accordance with examples of the disclosure can be represented by the formula SiₐC_{b}H_{c}O_{d}Nₑ, where a is a natural number no less than 1 and no greater than 5, b is a natural number no less than 1 and no greater than 20, c is a natural number no less than 1 and no greater than 40, d is 0 or a natural number no greater than 10, and e is 0 or a natural number no greater than 5. The precursor can include a chain or cyclic molecule having one or more carbon atoms, one or more silicon atoms, and one or more hydrogen atoms, such as molecules represented by the formula above.

By way of examples, the precursor can include one or more of a silazane, a silylamine, or a silicon alkylamine. For example, the precursor can be or include one or more of hexamethyldisilazane, divinyltetramethyldisilazane, tetramethyldisilazane or etrasilyl-silanediamine.

A flowrate of the precursor from a precursor source to the reaction chamber can vary according to other process conditions. By way of examples, the flowrate of the precursor, alone or mixed with a carrier gas, can be from about 100 sccm to about 3,000 sccm. Similarly, a duration of each pulse of providing a precursor to the reaction chamber can vary, depending on various considerations. By way of examples, the duration of a precursor pulse for each cycle can range from about 3 seconds to about 60 seconds.

During step 104, a plasma can be formed for a deposition plasma power pulse period. The plasma can be a direct plasma. A power used to ignite and maintain the plasma can range from about 50 W to about 800 W. A frequency of the power can range from about 400 kHz to about 60 MHz. A duration the deposition plasma power pulse period (e.g., for each deposition cycle) can be between about 3 and about 60 seconds. In some cases, the plasma power may be provided after ceasing or decreasing the flow of the precursor to the reaction chamber.

During step 104, the precursor is converted into the initially viscous, flowable material using excited species. The flowable material can flow into the recesses and can become deposited material within the recesses. The deposited material can become solid or substantially solid.

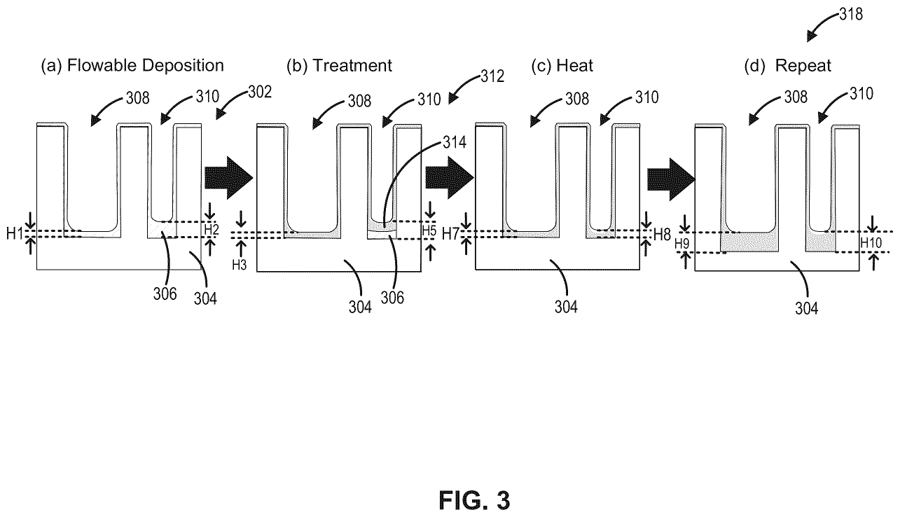

FIG. 3 (a) illustrates a structure 302 that includes a substrate 304 having a first recess 308 and a second recess 310 and deposited material 306 formed within first and second recesses 308, 310. Substrate 302 and recesses 308, 310, can be the same or similar to substrate 204 and recesses 208, 210. Deposited material 306 can be the same or similar to deposited material 206 and can be formed according to step 104 described above. As illustrated, a height H1 of deposited material 306 within recess 308 can be less than a height H2 of deposited material 306 within recess 310. In accordance with examples of the disclosure H1 or H2—i.e., a thickness of the deposited material at a bottom of the recess is between about 5 nm and about 30 nm. Using a thickness in this range can facilitate even height gap fill processes as described herein.

After deposited material 306 is formed within recesses 308, 310, deposited material 306 is treated to form treated material 314 and structure 312. As illustrated, structure 312 includes treated material 314 within recesses 308, 310 and includes deposited material 306 in at least recess 310. As shown, at this stage a height H4 of deposited material 306 and treated material 314 within recess 310 is greater than a height H3 of treated material 314 within recess 308.

During treatment step 106, activated species within the reaction chamber are used to form treated material. Treatment step 106 can be used to tune desired properties of material within the recesses, such as density, etch resistance, and the like.

During treatment step 106, a treatment gas is used to form treatment activated species. The treatment activated species can be formed by providing a treatment gas within the reaction chamber and forming a plasma. The treatment gas can be or include, for example, hydrogen (H₂). A flowrate of the treatment gas can be between about 50 and about 500 sccm. If performed after multiple deposition cycles, a duration of step 108 can be between about 30 and about 600 seconds or between about 60 and about 180 seconds

A power used to form the plasma during step 106 can be less than or equal to 2000 W or between about 400 W and about 600 W; a frequency of the power can range from about 400 kHz and no greater than 60 MHz. In some cases, the plasma power during step 106 can be pulsed—e.g., at a frequency between about 1,000 and about 10,000 Hz and/or with a duty cycle of about 50. Additionally or alternatively, a plasma power provided during step 106 can include a first frequency and a second frequency different from the first frequency. The first frequency can be no less than 15.56 MHz and no more than 60 MHz and/or the second frequency can be no less than 100 kHz and no more than 13.56 MHz. A duration of treatment plasma power during step 106 (e.g., for each deposition cycle) can be between about 3 and about 60 seconds or between about 10 and about 30 seconds.

A temperature (T3) within the reaction chamber during the step of treating can be greater than or equal to T1. T3 can also be less than T2, described below. A pressure within a reaction chamber during step 106 can be from about 100 Pa to 1,000 Pa.

Step 106 can be performed in the same reaction chamber as steps 102 and/or 104.

During step 108, the substrate including the treated material (e.g., treated material 314) is heated at a second temperature (T2) to remove a at least a portion of remaining the deposited material (306). In accordance with examples, T2 is greater than T1.

As illustrated in FIG. 3 (c), during step 108, any remaining deposited material (e.g., untreated or undertreated material) 306 can be removed, which lowers a height of material within recess 310, such that a height of material within recesses of varying aspect ratios (308, 310) is about the same. That is, height H7 and H8 of heated material 316 are about the same (e.g., within about 1 or 10 percent of each other).

Step 108 can include heating the substrate to a temperature T2 that is, for example, about 150 to about 600° C. greater than T1. T2 can be, for example, greater than or equal to 300° C. or between about 300° C. and about 600° C. or between about 300° C. and about 500° C.

Step 108 of heating can include providing one or more of argon, nitrogen, helium, hydrogen, and/or ammonia to the reaction chamber. A pressure within the reaction chamber during step 108 can be between about 10 Pa and about 3000 Pa or between about 300 Pa and about 2000 Pa or between about 300 Pa and about 1500 Pa. A duration of step 108 can be between about 30 and about 600 seconds or between about 60 and about 180 seconds.

Step 108 can be performed in the same reaction chamber used during steps 102-106 or in another reaction chamber—e.g., another reaction chamber of a cluster tool. The heating can be performed using one or more substrate heaters and/or lamps.

As illustrated, method 100 can include a repeat loop 110 that includes steps 104 and 106 and/or a repeat loop 112 that includes steps 104-106 and optionally loop 110. Steps 104-108 can be repeated to, for example, fill a recess, such as recess 308 and/or 310.

FIG. 3 (d) illustrates a structure 318 after repeating steps 104-108 of method 100 a number of times. As illustrated a height H9 and H10 of heated material 316 are about the same-even after a number of deposition cycles.

Method 100 can also include purge steps. For example, a purge step can be performed between cycles of a cyclical deposition process and/or between steps of method 100. In some cases, a reactant can be used during a purge step.

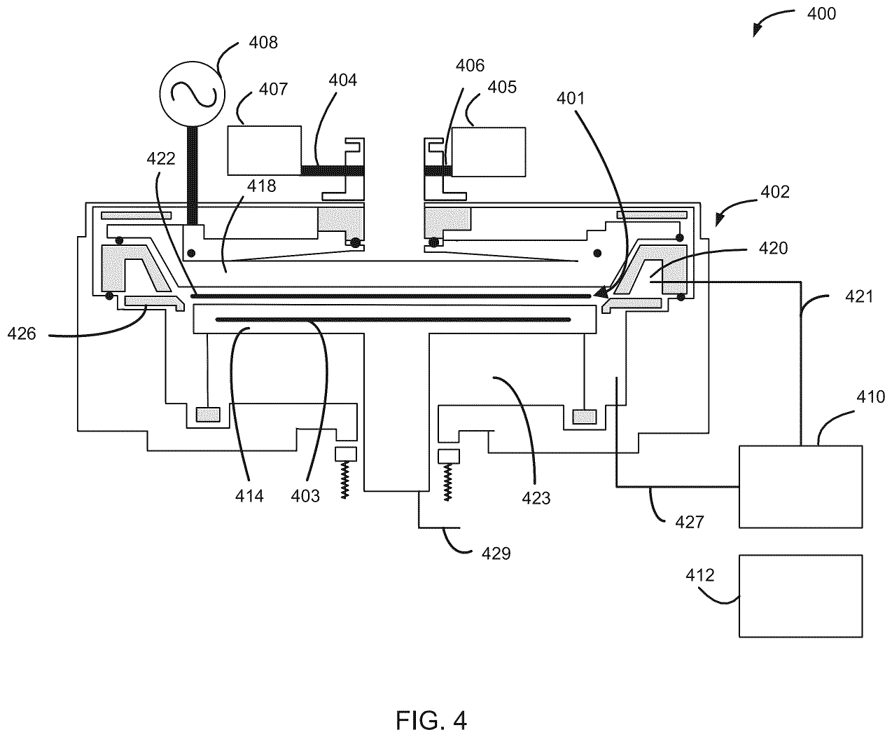

Turning now to FIG. 4, a reactor system 400 in accordance with exemplary embodiments of the disclosure is illustrated. Reactor system 400 can be used to perform one or more steps or substeps as described herein and/or to form one or more structures or portions thereof as described herein. Reactor system 400 is illustrated as a capacitively coupled plasma (CCP) apparatus. In accordance with alternative examples of the disclosure, the plasma power provided during one or more steps can be formed using a surface wave plasma (SWP) apparatus, an inductively coupled plasma (ICP) apparatus, or an electron cyclotron resonance (ECR) apparatus.

Reactor system 400 includes a pair of electrically conductive (e.g., flat-plate) electrodes 414, 418, typically in parallel and facing each other in an interior 401 (reaction zone) of a reaction chamber 402. Although illustrated with one reaction chamber 402, reactor system 400 can include two or more reaction chambers. A plasma can be excited within interior 401 by applying, for example, RF power from plasma power source(s) 408 to one electrode (e.g., electrode 418) and electrically grounding the other electrode (e.g., electrode 414). A temperature regulator 403 (e.g., to provide heat and/or cooling) can be provided in a lower stage 414 (the lower electrode), and a temperature of a substrate 422 placed thereon can be kept at a desired temperature, such as the temperatures noted above. Electrode 418 can serve as a gas distribution device, such as a shower plate or showerhead. Precursor gases, reactant gases, and a carrier or inert gas, if any, or the like can be introduced into reaction chamber 402 using one or more gas lines (e.g., reactant gas line 404 and precursor gas line 406, respectively, coupled to a reactant source 407 and a precursor (e.g., a precursor as described above) source 405). For example, an inert gas and a reactant (e.g., as described above) can be introduced into reaction chamber 402 using line 404 and/or a precursor and a carrier gas (e.g., as described above) can be introduced into the reaction chamber using line 406. Although illustrated with two inlet gas lines 404, 406, reactor system 400 can include any suitable number of gas lines.

In reaction chamber 402, a circular duct 420 with an exhaust line 421 can be provided, through which gas in the interior 401 of the reaction chamber 402 can be exhausted to an exhaust source 410. Additionally, a transfer chamber 423 can be provided with a seal gas line 429 to introduce seal gas into the interior 401 of reaction chamber 402 via the interior (transfer zone) of transfer chamber 423, wherein a separation plate 426 for separating the reaction zone and the transfer chamber 423 can be provided (a gate valve through which a substrate is transferred into or from transfer chamber 423 is omitted from this figure). Transfer chamber 423 can also be provided with an exhaust line 427 coupled to an exhaust source 410. In some embodiments, continuous flow of a carrier gas to reaction chamber 402 can be accomplished using a flow-pass system (FPS).

Reactor system 400 can include one or more controller(s) 412 programmed or otherwise configured to cause one or more method steps as described herein to be conducted. Controller(s) 412 are coupled with the various power sources, heating systems, pumps, robotics and gas flow controllers, or valves of the reactor, as will be appreciated by the skilled artisan. By way of example, controller 412 can be configured to control gas flow of a precursor, a reactant, and/or an inert gas into at least one of the one or more reaction chambers to form a deposited, treated, or heated material as described herein. Controller 412 can be further configured to provide power to form a plasma—e.g., within reaction chamber 402. Controller 412 can be similarly configured to perform additional steps as described herein.

Controller 412 can include electronic circuitry and software to selectively operate valves, manifolds, heaters, pumps and other components included in system 400. Such circuitry and components operate to introduce precursors, reactants, and purge gases from the respective sources. Controller 412 can control timing of gas pulse sequences, temperature of the substrate and/or reaction chamber, pressure within the reaction chamber, plasma power, and various other operations to provide proper operation of the system 400, such as in the performance of method 100.

Controller 412 can include control software to electrically or pneumatically control valves to control flow of precursors, reactants, and/or purge gases into and out of the reaction chamber 402. Controller 412 can include modules, such as a software or hardware component, e.g., a FPGA or ASIC, which perform certain tasks. A module can advantageously be configured to reside on the addressable storage medium of the control system and be configured to execute one or more processes.

In some embodiments, a dual chamber reactor (two sections or compartments for processing substrates disposed close to each other) can be used, wherein a reactant gas and a noble gas can be supplied through a shared line, whereas a precursor gas is supplied through unshared lines.

During operation of system 400, substrates, such as semiconductor wafers, are transferred from, e.g., a substrate handling area 423 to interior 401. Once substrate(s) are transferred to interior 401, one or more gases, such as precursors, reactants, carrier gases, and/or purge gases, are introduced into reaction chamber 402.

The example embodiments of the disclosure described above do not limit the scope of the invention, since these embodiments are merely examples of the embodiments of the invention. Any equivalent embodiments are intended to be within the scope of this invention. Indeed, various modifications of the disclosure, in addition to the embodiments shown and described herein, such as alternative useful combinations of the elements described, may become apparent to those skilled in the art from the description. Such modifications and embodiments are also intended to fall within the scope of the appended claims.

What is claimed is:

1. A method of forming material within a recess on a surface of a substrate, the method comprising:
providing a substrate within a reaction chamber;
forming a flowable material at a first temperature (T1) within the reaction chamber, the flowable material forming deposited material within the recess;
treating the deposited material using activated species within the reaction chamber to form treated material; and
heating the substrate including the treated material at a second temperature (T2) to remove a portion of the deposited material,
wherein T2 is greater than T1.

2. The method according to claim 1, wherein a thickness of the deposited material at a bottom of the recess is between about 5 nm and about 30 nm.

3. The method according to claim 1, wherein T2 is about 150 to about 600° C. greater than T1.

4. The method according to claim 1, wherein T1 is less than or equal to 150° C. or between about 30° C. and about 100° C. or between about 50° C. and about 90° C.

5. The method according to claim 1, wherein T2 is greater than or equal to 300° C. or between about 300° C. and about 600° C. or between about 300° C. and about 500° C.

6. The method according to claim 1, wherein a temperature (T3) during the step of treating is greater than or equal to T1.

7. The method according to claim 1, wherein T3 is less than T2.

8. The method according to claim 1, wherein the step of forming the flowable material comprises a cyclical deposition process.

9. The method according to claim 8, wherein the cyclical deposition process comprises:
providing a precursor to the reaction chamber for a precursor pulse;
providing a reactant to the reaction chamber; and
providing a plasma power for a deposition plasma power pulse period.

10. The method according to claim 9, wherein the precursor comprises silicon and nitrogen.

11. The method according to claim 9, wherein the precursor comprises one or more of a silazane, a silylamine, or a silicon alkylamine.

12. The method according to claim 9, wherein the reactant comprises one or more of argon, nitrogen, or hydrogen.

13. The method according to claim 1, wherein during the step of heating, one or more of argon, nitrogen, helium, hydrogen, and/or ammonia are provided to the reaction chamber.

14. The method according to claim 1, wherein a pressure within the reaction chamber during the step of heating is between about 10 and about 3000 or between about 300 Pa and about 2000 Pa or between about 300 Pa and about 1500 Pa.

15. The method according to claim 1, wherein the step of treating comprises providing a treatment gas comprising hydrogen to the reaction chamber.

16. The method according to claim 1, comprising repeating the steps of forming the flowable material, treating the deposited material, and heating the substrate.

17. The method according to claim 1, wherein the step of heating is performed within the reaction chamber.

18. The method according to claim 1, wherein the heating is performed using substrate heaters and/or lamps.

19. The method according claim 1, comprising repeating the steps of forming the flowable material and treating the deposited material prior to the step of heating the substrate.

20. A structure formed according to the method of claim 1.

21. A system comprising:
a reactor comprising a reaction chamber; and
a controller configured to perform a method according to claim 1.
